(19) United States
(12) Patent Application Publication
(10) Pub. No.: US 2011/0043236 A1
(43) Pub. Date: Feb. 24, 2011

(54) COMPRESSION CONNECTOR MODULE FOR USE WITH STORAGE DEVICES AND A TEST CARRIER INCORPORATING SAME

(75) Inventor: Bee Keong Ng, Singapore (SG)

Correspondence Address: COHEN, PONTANI, LIEBERMAN & PAVANE LLP, 551 FIFTH AVENUE, SUITE 1210, NEW YORK, NY, 10176, US

(73) Assignee: Innovative Polymers PTE. Ltd, Singapore (SG)

(21) Appl. No.: 12/297,685

(22) PCT Filed: May 31, 2006
(86) PCT No.: PCT/SG2006/000136

§ 371 Date: Jan. 16, 2009

(51) Int. Cl. G01R 31/00; H01R 13/62

(52) U.S. Cl. 324/756.01; 439/329

(57) ABSTRACT

A compression connector module (10) for use with storage devices comprising a connector housing (12); at least one connector pin (16) mounted on the connector housing (12); and a flex clamp (14) positioned such that a clamping portion (32) of the flex clamp (14) overlays at least one of the at least one connector pins (16) when oriented to a closed position, wherein, when the clamping portion (32) is set to a first position a cable connected to the storage device can sit on the at least one connector pin (16) and when the clamping portion (32) is set to a second position force is applied to the cable in the direction of the at least one connector pin (16) so as to reasonably secure a connection between the cable and the at least one connector pin (16) such that electrical signals provided to the at least one connector pin (16) can be communicated to the cable.

### FIELD OF THE INVENTION

The present invention relates to a compression connector module for use with storage devices and a test carrier incorporating same. In particular the storage device has a flexible printed circuit (“FPC”) cable integral, or attached, thereto.

The invention is ideally suited to testing sub 3.5″ inch storage devices, hereafter referred to as small form factor (“SFF”) storage devices in a 3.5″ hard disk drive tester.

### BACKGROUND TO THE INVENTION

The following discussion of the background to the invention is intended to facilitate an understanding of the present invention. It should be appreciated that the discussion is not an acknowledgment or admission that any of the material referred to was published, known or part of the common general knowledge in any jurisdiction as at the priority date of the application.

In all high-precision manufacturing processes, the produce manufactured is subject to certain quality control requirements. This generally involves testing using one or more testing devices.

In the manufacture of storage devices, and in particular SFF storage devices, there are a number of problems that the manufacturer is presented with, such as the following:
Testing beds are typically designed for 3.5″ storage devices. Testing beds of alternative sizes need to be custom made which delays the time to market of SFF storage devices.
Some SFF storage devices only have an FPC connector integrated therein. This poses further problems in that:
   Testing beds, as mentioned in the previous point, are not designed to facilitate connection with such FPC connectors;
   The FPC connector has not been designed to be robust due to the limited number of connections it is expected to make in its lifetime. However, during testing the FPC connector may undergo a number of connect/disconnect cycles—thereby increasing the risk of breakage of the FPC connector.

It is therefore an object of the present invention to overcome, at least in part, some or all of the aforementioned problems.

### SUMMARY OF THE INVENTION

Throughout this document, unless otherwise indicated to the contrary, the terms “comprising”, “consisting of”, and the like, are to be construed as inclusive and not exhaustive.

In accordance with a first aspect of the invention there is a compression connector module (“CCM”) for use with storage devices comprising:
a connector housing;
at least one connector pin mounted on the connector housing; and
a flex clamp positioned such that a clamping portion of the flex clamp overlays at least one of the at least one connector pins when oriented to a closed position,
   wherein, when the clamping portion is set to a first position a cable connected to the storage device can sit on the at least one connector pin and when the clamping portion is set to a second position force is applied to the cable in the direction of the at least one connector pin so as to reasonably secure a connection between the cable and the at least one connector pin such that electrical signals provided to the at least one connector pin can be communicated to the cable.

Preferably, the flex clamp is positioned such that the clamping portion overlaps all of the at least one connector pins when oriented to a closed position. The flex clamp may be removable. Alternatively, the clamping portion of the flex clamp may be removable.

The at least one connector pin may be resilient, thereby minimising the potential for damage to be caused by a cable when the clamping portion is set to the second position. The connector pins may also be arranged in different configurations. In an alternating row configuration, this allows the non-cable contacting end of the connector pins to also form spaced alternating rows and thereby minimise electrical interference between connector pins.

The CCM may be provided with chamfered guides mounted to sides of the connector housing, the guides adapted to facilitate positioning of the cable on to the at least one connector pins.

In accordance with a second aspect of the invention there is provided a test carrier adapted to be removable received in a plurality of test beds, the test carrier comprising:
1. a carrier base;
2. at least one CCM as described in the first aspect of the invention mounted to the carrier base; and
3. at least one host interface,
   wherein each host interface is in electrical communication with the at least one connector pin of a CCM and where, when the test carrier is received in a test bed, electrical signals generated by the test bed are communicated to any cables received within a CCM by way of its associated host interface and at least one connector pin.

Preferably, the test carrier further comprises a slider operable between a first position and a second position. With the slider located at the first position the CCM has freedom of operation. However, in moving the slider from the first position to the second position, the slider applies force to the clamping portion so as to move and maintain the clamping portion at its closed position when the slider reaches the second position. Releasable retention clips may also be provided to facilitate maintenance of the slider at the second position.

The carrier base may have at least one recessed portion, each recessed portion adapted to receive a storage device under test. The slider may also include holding fingers for providing a dampening force to the storage devices received within the at least one recessed portion.

The slider may also have a handle to facilitate movement between the first and second positions.

The clamping portion of the CCM may be biased to the open position.

### BRIEF DESCRIPTION OF THE DRAWINGS

The following invention will be described with reference to the following drawings of which:

FIG. 1 is an isometric view of a CCM in accordance with a first embodiment of the invention.

FIG. 1a is an isometric view of a first cross-section of the CCM shown in FIG. 1.

FIG. 1b is an isometric view of a second cross-section of the CCM shown in FIG. 1.

FIG. 2 is an isometric view of the CCM shown in FIG. 1 in its first position, the CCM having a FPC cable received therein.

FIG. 3 is an isometric view of the CCM shown in FIG. 1 in its second position, the CCM clamping a FPC cable received therein.

FIG. 4 is a partly exploded isometric view of a flex clamp used in a CCM shown in FIG. 1.

FIG. 5 is an isometric view of a test carrier in accordance with a second embodiment of the invention.

FIG. 6 is an isometric view of the test carrier shown in FIG. 5 in its first position, the test carrier having a SFF storage device with a FPC cable attached thereto.

FIG. 7 is an isometric view of the test carrier shown in FIG. 5 in its second position, the test carrier having a SFF storage device with a FPC cable attached thereto.

FIG. 8 is an isometric view of a test carrier having multiple SFF storage device testing capabilities.

### PREFERRED EMBODIMENTS OF THE INVENTION

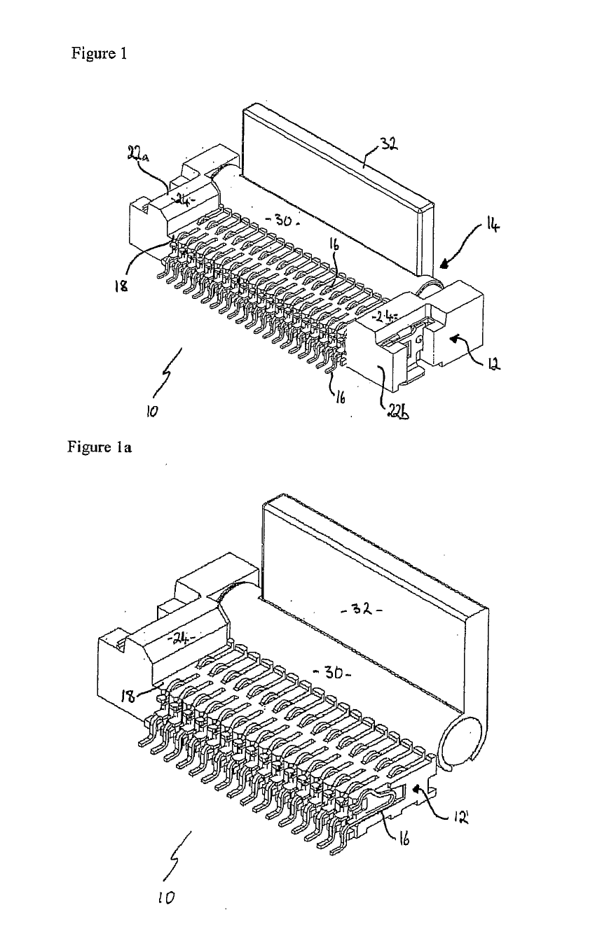

In accordance with a first embodiment of the invention there is a CCM 10 as shown in FIG. 1. The CCM 10 comprises a connector housing 12 and a flex clamp 14.

The connector housing 12 has a set of connector pins 16 provided on an exposed surface 18 of the connector housing 12. The set of connector pins 16 are arranged in an alternating pattern on the top surface 18. In this manner, two rows of connector pins 16 are formed on the top surface 18.

Each connector pin 16 curls back on itself to allow for soldering to a circuit board on which the CMM 10 is to be mounted. The configuration of the connector pins 16 are shown graphically in FIGS. 1a and 1b.

The connector housing 12 also has opposing ends 22a, 22b. Provided at each opposing end 22a, 22b are chamfered guides 24. Adjacent the chamfered guide 24, at opposing end 22a, is a cylindrical protrusion 26. A rectangular protrusion 28 is positioned adjacent the guide 24 at opposing end 22b.

The flex clamp 14 comprises a cylindrical retaining portion 30 and a clamping portion 32. The cylindrical retaining portion 30 is hollow with an opening 33 at one end. At the other end of the cylindrical retaining portion 30 is a cylindrical recess 31. Separating the cylindrical recess 31 from the opening 33 is a solid portion (not shown).

A plunger 34 having a torsion spring 36 attached thereto is adapted to be received within the cylindrical retaining portion 30. The plunger 34 has a rectangular recess 38 provided therein.

The clamping portion 32 is of similar size and shape to the top surface 18.

In constructing the CCM 10, the cylindrical retaining portion 30 is aligned next to the connector housing 12 such that the clamping portion 32 is spaced from the top surface 18. The plunger 34 is then received within the opening 33 of the cylindrical retaining portion 30 such that the torsion spring 36 is aimed towards the cylindrical protrusion 26.

The cylindrical retaining portion 30 is then positioned such that the cylindrical protrusion 36 is received within the cylindrical recess 31. In this position, the torsion spring 36 contacts the solid portion. Compression of the torsion spring 36 then allows the plunger 34 to retract into the cylindrical retaining portion 30. Following retraction of the plunger 34, the cylindrical retaining portion 30 can be re-positioned to allow the rectangular recess 38 to align with the rectangular protrusion 28. Compression of the torsion spring 36 is then relaxed causing the flex clamp 14 to be securely retained to the connector housing 12.

The embodiment will now be described in the context of its intended use with a FPC Cable 40.

The FPC cable 40 in this example comprises a series of multiple flat electrical conductors laminated between layers of flexible polymer materials. The ends of each flat electrical conductor has an expanded [conductor] surface area. This expanded surface area is hereafter referred to as a pad. The FPC cable 40 has a width substantially equal to the distance between the chamfered guides 24.

The CCM 10 is wired such that electrical signals can be provided to, and received from, the connector pins 16. The FPC cable 40 is then positioned such that it is above the exposed surface 18. The FPC cable 40 is then guided into a contact position with the exposed surface 18 using the chamfered guides 24 as required.

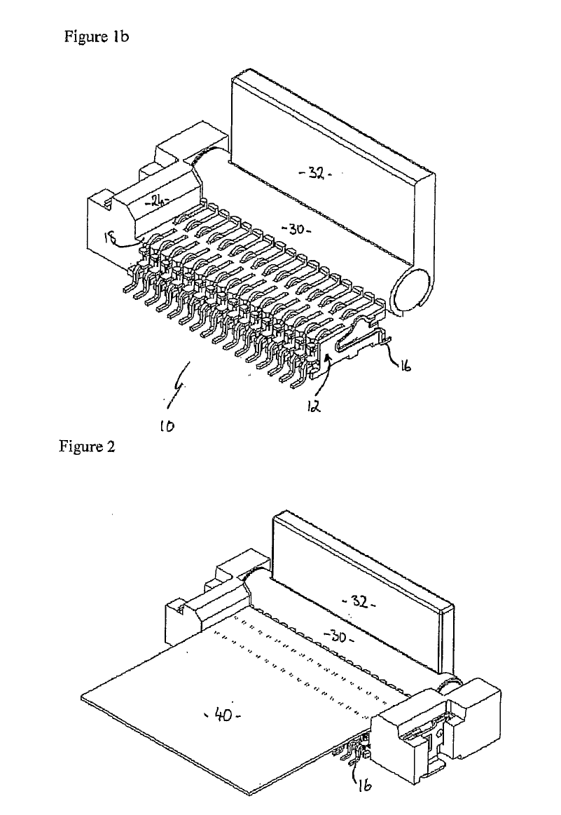

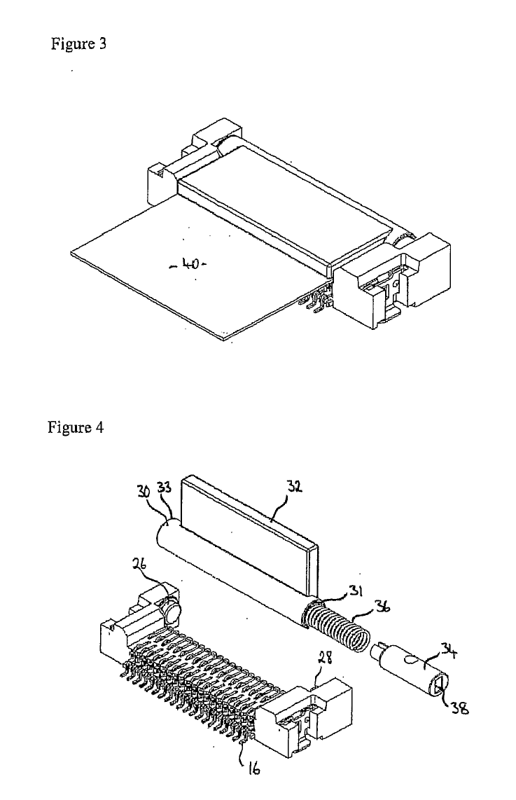

Once contact between the FPC cable 40 and exposed surface 18 is achieved, the clamping portion 32 is rotated to a second position as shown in FIG. 3 (FIG. 2 shows the cylindrical retaining portion 30 in its open position). On completion of the rotation to the closed position, the cylindrical retaining portion 30 clamps the FPC cable 40 against the exposed surface 18. This allows each pad to make a connection with a connector pin 16. On connection, electrical signals can travel through connector pins 16 and from there to the pads of the FPC cable 40. This then allows the SFF device (not shown) to which the FPC cable 40 is connected to be tested as required.

In accordance with a second embodiment of the invention there is a test carrier 100. In the embodiment shown in FIG. 5, the test carrier 100 is for a single unit 1 inch SFF storage device.

The test carrier 100 comprises a carrier base 102, a slider 104 and a CCM 10 as described in the first embodiment of the invention.

The carrier base 102 has a recessed area 106 and a host interface printed circuit board assembly 107. The recessed area 106 is sufficiently sized and shaped to receive a SFF storage device. Two “C”-shaped sliding channels 108 sit either side of the recessed area 106. In between the two sliding channels 108 is a rear abutment 110.

The host interface printed circuit board assembly 107 is adapted to interface the 3.5″ test bed apparatus (not shown). When connected to the 3.5″ test bed apparatus, through circuitry also not shown, electrical signals generated by the test bad apparatus can be conveyed to the SFF storage device via the connector pins 16, 20.

The slider 104 is positioned such that a portion thereof is received within two sliding channels 108. When set to a first position, the slider 104 abuts the rear abutment 110.

The slider 104 also has an aperture 112 therein. When set to the first position, the aperture 112 substantially corresponds in size and shape to the recessed area 106.

The slider 104 further comprises a handle 114 and holding fingers 116. The handle 114 is positioned at a free end 120 of the slider (ie. The end that does not abut the rear abutment 110). The holding fingers 116 extend form the slider at a position such that they provide sides to the CCM 10.

The second embodiment of the invention will now be described in the context of the following example.

In this embodiment the SFF storage device only has an FPC connector (not shown) provided thereon. Accordingly, an FPC cable is attached to the FPC connector using an appropriate mating relationship, such as male/female connectors, as would be known to the person skilled in the art. When so attached, the pads of the FPC cable remain exposed for receipt into the CCM 10.

In its first position as shown in FIG. 5, the aperture 112 remains empty. The SFF storage device to be tested, with FPC cable attached, is inserted into the aperture 112. In doing so, the FPC cable is orientated to overlap the exposed surface 18 of the CCM 10—with the help of the chamfered guides 24 as required.

Once the SFF storage device is received within the aperture 112, the tester moves the slider 104 from the first position to a second position. The tester may do this by personally gripping the handle 114 and effecting the movement of the slider 104. Alternatively, the tester may employ another mechanism, such as a robotic arm, to grip the handle 114 and effect the movement of the slider 104.

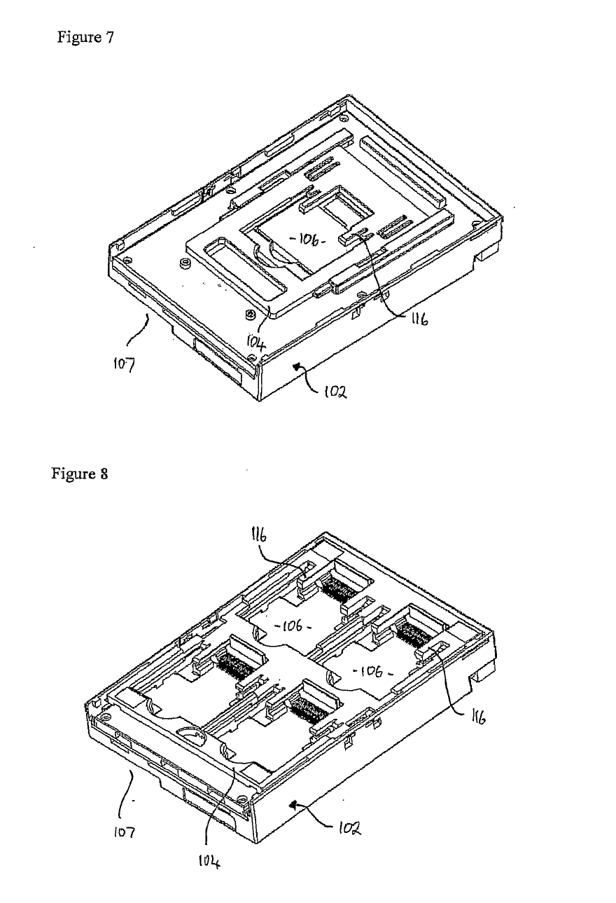

Movement of the slider 104 form the first position to the second position causes the following:
a space is created between the slider 104 and the rear abutment 110;
holding fingers 116 overlay the SFF storage device. The holding fingers 116 then act as dampeners while the SFF storage device is under test; and
part of the slider 104 comes, firstly, into contact with the clamping portion 32 of the flex clamp 14. Further movement then causes the flex clamp 14 to rotate about the plunger 34 towards its second position. Eventually, such movement results in the flex clamp 14 settling in the second position allowing the slider 104 to sit in a position over the top of the flex clamp 14. This is shown in FIG. 7.

With the slider 104 sitting over the top of the flex clamp 14, the flex clamp 14 applies pressure to the FPC cable 40. This pressure allows the pads of the FPC cable 40 to form a solid connection with the connector pins 16 of the CMM 10.

When so connected, as described above, signals generated by the test bed apparatus can be conveyed to the SFF storage device via the connector pins 16, 20 and the flex cable 40.

After testing, the SFF storage device can be removed by reversing the procedure set out above.

A further aspect of this embodiment of the invention is that the whole test carrier 100 may be removed from the 3.5″ testing bed at any time without need to remove the FPC cable from the CCM 10. In addition, the SFF storage device together with the FPC cable can be removed from the test carrier without the need to remove FPC cable from the FPC connector of the SFF storage device. In this manner, the number of connect/disconnect cycles the FPC connector must go through is greatly reduced with an appropriate corresponding reduction in risk of breakage.

It should be appreciated by the person skilled in the art that the present invention is not limited to the embodiments described. In particular the following additional features may be incorporated to form yet further embodiments:
The CCM 10 may be modified to adapt FPC cables of different configurations to that described. For example, the CCM 10 may be modified to include a differing number of connector pins 16, 20 to that shown in the respective Figures.
Alternatively, or in conjunction, the CCM 10 may also be modified to accept cables other than FPC cables.
The chamfered guides 24 may be omitted.
The connector pins 16 may be arranged in differing configurations to that specified in the above description and shown in the accompanying figures. For example, a single row or triangular pattern configuration could be used in place of the alternating row configuration shown.
Similarly, the connector pins 16 may take a different shape to the configuration shown in the Figures. For example, the connector pins may take an “L” shape with the smaller side being exposed for connection to the FPC cable and the longer side being adapted for connection to the test carrier to which the CCM is to be mounted.
Other forms of connecting the flex clamp 14 to the CCM 10 may be implemented. For instance, the flex clamp 14 could be an integral part of the CCM 10 or could be connected to the CCM 10 by way of a round metal pin extending through the internal hollow of the cylindrical retaining portion 30.
The flex clamp 14 may be attached to an external housing in close proximity to the connector housing 12.
The test carrier 100 may be adapted to be used in storage device tester units having a test bed size greater than or less than the 3.5″ HDD tester unit mentioned above.
The test carrier 100 may be adapted to test storage devices 40 other than SFF storage devices. It should be understood however, that the invention has particular suitability for use with SFF storage devices.
The torsion spring 36 may be configured so as to bias the flex clamp 14 to a first position.
The CCM 10 may contain circuitry as would be known to the person skilled in the art to provide an appropriate connection between a tester interface provided for in the carrier base 102 (either internally or externally) and the FPC cable. Such circuitry must also be capable of handling the appropriate communication protocols as required by the type of SFF storage device being tested.
In a variation of the second embodiment, the slider 104 may be provided with retention clips that engage suitable retaining mechanisms provided for on the carrier base 102 when the slider 104 moves from the first position to the second position. Alternatively, other forms of retaining the slider 104 in the second position may be implemented.
The carrier base 102 and associated components can be modified from that described in the second embodiment to allow for multiple SFF storage devices to be tested using a single carrier base 102 configuration.
The open position described above may not be representative of the flex clamp 14 being extended to its maximum open position. Similarly, the closed position may not be representative of the flex clamp 14 being placed at its fully closed position. Instead, the open position only need represent a position where the FPC cable may be removed from the CCM 10. The closed position only need represent a position where pressure is applied to the FPC cable to form a reasonably secure connection between the pads of the FPC cable and the connector pins 16.
The test carrier may be adapted to facilitate the testing of multiple storage devices using a single slider configuration slightly modified from that described above, but as would be well within the capabilities of the person skilled in the art. FIG. 8 shows an example of such a test carrier.

It should be further appreciated by the person skilled in the art that the features described above, where not mutually exclusive, can be combined to form yet further embodiments of the invention.

1. A compression connector module for use with storage devices comprising:
a connector housing;
at least one connector pin mounted on the connector housing; and
a flex clamp having a clamping portion biased to a first position where a cable connected to the storage device can contact the at least one connector pin, where, when a primary force is applied to the clamping portion, the clamping portion rotates about a fixed position to a point where a secondary force is applied to the cable so as to reasonably secure a connection between the cable and the at least one connector pin in a manner as to allow electrical signals to be communicated to the cable by way of the at least one connector pin.

2. A compression connector module for use with storage devices according to claim 1, where the flex clamp is positioned such that the clamping portion overlaps all of the at least one connector pins when oriented to a closed position.

3. A compression connector module for use with storage devices according to claim 1, where the flex clamp is removable.

4. A compression connector module for use with storage devices according to claim 1, where the clamping portion of the flex clamp is removable.

5. A compression connector module for use with storage devices according to claim 1, where the at least one connector pin is resilient.

6. A compression connector module for use with storage devices according to claim 1, where the at least one connector pin is arranged in an alternating row configuration on the connector housing.

7. A compression connector module for use with storage devices according to claim 1, further comprising chamfered guides mounted to sides of the connector housing, the guides adapted to facilitate positioning of the cable on to the at least one connector pins.

8. A test carrier adapted to be removable received in a plurality of test beds, the test carrier comprising:
a carrier base;
at least one CCM as described in claim 1; and
at least one host interface,
wherein each host interface is in electrical communication with the at least one connector pin of a CCM and where, when the test carrier is received in a test bed, electrical signals generated by the test bed are communicated to any cables received within a CCM by way of its associated host interface and at least one connector pin.

9. A test carrier according to claim 8, further comprising a slider operable between a first position and a second position, such that, when the slider is located at the first position the CCM has freedom of operation and when the slider is moved from the first position to the second position, the slider applies force to the clamping portion so as to move and maintain the clamping portion at its closed position when the slider reaches the second position.

10. A test carrier according to claim 9, further including releasable retention clips mounted on the carrier base to facilitate maintenance of the slider at the second position.

11. A test carrier according to claim 9, wherein the carrier base has at least one recessed portion, each recessed portion adapted to receive a storage device under test and the slider may also includes holding fingers for providing a dampening force to the storage devices received within the at least one recessed portion.

12. A test carrier according to claim 9, where the slider has a handle to facilitate movement between the first and second positions.

13. A test carrier according to claim 9, where the clamping portion of the compression connector module is biased to the open position.

14. A compression connector module substantially as described herein with reference to FIGS. 1 to 4;

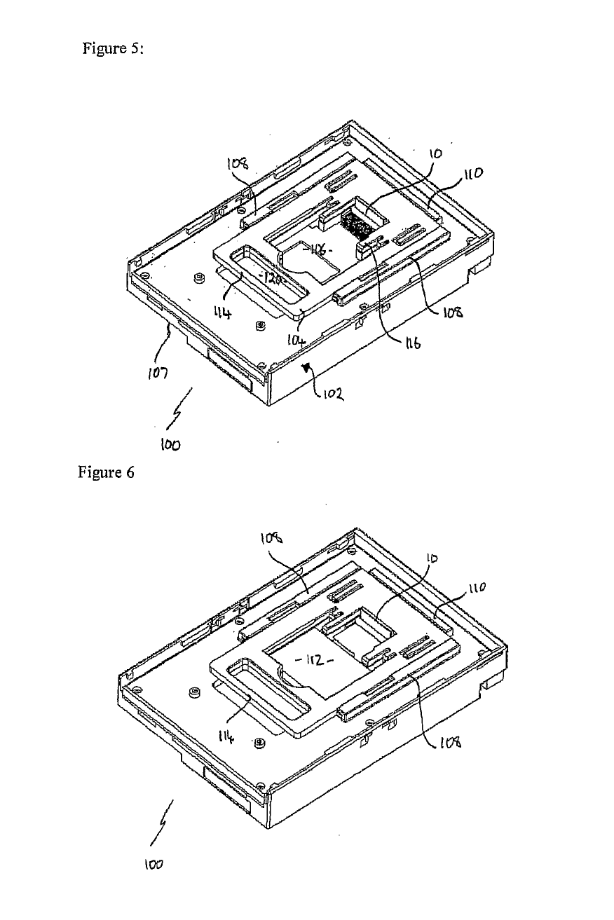

15. A test carrier substantially as described herein with reference to FIGS. 5 to 8.
